(19) United States
(12) Patent Application Publication
(10) Pub. No.: US 2016/0356842 A1
(43) Pub. Date: Dec. 8, 2016

(54) MILLIMETER WAVE POGO PIN CONTACTOR DESIGN

(71) Applicant: Advantest Corporation, Tokyo (JP)

(72) Inventor: Donald LEE, San Jose, CA (US)

(21) Appl. No.: 14/728,699

(22) Filed: Jun. 2, 2015

(51) Int. Cl. G01R 31/28; G01R 1/04; H01R 43/20; H01R 12/70; H01P 5/08

(52) U.S. Cl. CPC G01R 31/2889; H01R 12/7076; H01P 5/08; H01R 43/205; G01R 31/2834; G01R 1/0483; G01R 1/0466

(57) ABSTRACT

An apparatus for testing DUTs is disclosed. The apparatus comprises a socket operable to enable coupling between a Ball Grid Array (BGA) packaged DUT and a Printed Circuit Board (PCB), wherein the socket comprises a plurality of pogo pin connectors. The apparatus also comprises a pogo pin connector operable to couple a ball on the BGA packaged DUT to a trace on the PCB, wherein the pogo pin connector comprises a first end in contact with the ball on the BGA packaged DUT and a second end in contact with the PCB, wherein the first end is thicker than a shaft of the pogo pin connector, wherein the PCB comprises at least a ground plane and a signal plane comprising signal traces, and wherein the ground plane is nearer to the second end relative to the signal plane.

### FIELD OF THE INVENTION

This invention relates generally to contactor systems for testing integrated circuits and, more specifically, to a contactor system for testing Ball Grid Array (BGA) packaged devices under test (DUTs).

### BACKGROUND OF THE INVENTION

A ball grid array (BGA) is a type of surface-mount packaging (a chip carrier) used for integrated circuits. BGA packages are used to permanently mount devices such as processors. A BGA can provide several interconnection pins, or balls, because the whole bottom surface of the device can be used, instead of just the perimeter. The leads are also on average shorter than with a perimeter-only type package leading to better performance at high speeds.

The balls at the bottom of a package for a conventional 0.5 mm BGA packaged DUT can fluctuate in size between 250 and 350 microns, with a 300-micron average size. In order to make reliable contact with the balls of the BGA in a high volume manufacturing environment, the contactor must be able to maintain proper contact despite a total ball height fluctuation of 150 microns. Accordingly, a reliable contactor needs to have 150-micron compliance.

A popular solution to the mechanical compliance problem is using a pogo pin contactor, which utilizes a spring-loaded cylindrical pogo. The pogo pin contactors are typically part of a socket in which the BGA packaged DUT is placed for testing. However, a limitation with pogo pin contactors is that they are typically 3 to 5 mm long, and at higher frequencies e.g., over 40 GHz, the inductance due to the pogo pin length limits high frequency performance. A design technique that is typically used by socket manufacturers (for the BGA packaged DUTs) to alleviate this problem is to suspend each pogo pin in a cylindrical hole in a metal block to create a coaxial transmission line. However, the maximum operating frequency despite using this technique is 40 GHz.

Another class of contactors that is typically used in the industry is conductive elastomer. The typical thickness of 0.14 mm for the elastomer creates minimal parasitic inductance, thereby, making elastomer an effective solution for 77-82 GHz testing. However, the contactor compliance for elastomers is relatively poor compared to pogo pins. For example, the approximate contactor compliance for elasatomer is about 40 microns, which is a small fraction of the required high volume manufacturing target of 150 microns. Additionally, elastomer contactors may not be as durable in a high volume manufacturing environment.

As a result, there is no current solution in the industry that offers both 80 GHz or so electrical performance and 150-micron mechanical compliance. Conductive elastomer contactors might provide electrical performance to 80 GHz, but mechanical compliance is limited to only approximately 40 microns. Pogo pin contactors, on the other hand, provide electrical performance only to 40 GHz, but mechanical compliance is limited to 150 microns.

### BRIEF SUMMARY OF THE INVENTION

Accordingly, there is a need for a contactor that has both 80 GHz electrical performance and 150 micron mechanical compliance. A typical application for these contactors, for example, is for use in testing devices to be incorporated into collision avoidance radar systems for automobiles. Many collision avoidance radar systems operate at frequencies of approximately 80 GHz or more because of the improved resolution available at those high frequencies. Accordingly, test systems for ICs to be incorporated into these types of radar systems need to provide a reliable solution for testing the high frequency parts.

A number of different automotive radar-based safety applications make use of frequencies from 76 to 77 GHz, for adaptive cruise control (ACC), blind-spot detection (BSD), emergency braking, forward collision warning (FCW), and rear collision protection (RCP). For example, in a collision warning system, an automotive radar sensor can detect and track objects within the range of the transmitted and returned radar signals, automatically adjusting a vehicle's speed and distance in accordance with the detected targets. Embodiments of the present invention advantageously provide cost-effective and efficient solutions for testing integrated circuits (ICs) to be used in automotive radar systems.

Embodiments of the present invention provide a pogo pin socket that has both 80 GHz millimeter wave test capability along with 150-micron compliance for rugged, reliable performance in a high volume manufacturing environment. Further, embodiments of the present invention provide a pogo pin contactor design that operates at millimeter wave frequencies and maintains a 50 ohm profile along its body.

In one embodiment, an apparatus for testing DUTs is disclosed. The apparatus comprises a socket operable to enable coupling between a Ball Grid Array (BGA) packaged DUT and a Printed Circuit Board (PCB), wherein the socket comprises a plurality of pogo pin connectors. The apparatus also comprises a pogo pin connector operable to couple a ball on the BGA packaged DUT to a trace on the PCB, wherein the pogo pin connector of the socket comprises a first end operable for contact with a ball on the BGA packaged DUT and a second end operable for contact with the PCB, wherein the first end is thicker than a shaft of the pogo pin connector, wherein the PCB comprises at least a ground plane and a signal plane comprising signal traces, and wherein the ground plane is nearer to the second end relative to the signal plane.

In one embodiment, a method of assembling a test system using pogo pin contactors. The method comprises positioning a socket to enable coupling between a Ball Grid Array (BGA) packaged DUT and a Printed Circuit Board (PCB), wherein the socket comprises a plurality of pogo pin connectors. The method further comprises coupling a ball on the BGA packaged DUT to a trace on the PCB using a pogo pin connector of the socket, wherein the pogo pin connector comprises a first end in contact with the ball on the BGA packaged DUT and a second end for contact with the PCB, wherein the first end is thicker than a shaft of the pogo pin connector. Finally, the method comprises contacting the second end of the pogo pin connector to the PCB, wherein a ground plane on the PCB is nearer to the second end relative to a plane with signal traces.

In a different embodiment, an automated testing equipment (ATE) apparatus is disclosed. The apparatus comprises a waveguide operable to communicate signals from a test head of the ATE to a Printed Circuit Board (PCB), wherein the PCB comprises signal traces operable to conduct signals. The apparatus also comprises a socket to enable coupling between a Ball Grid Array (BGA) packaged DUT and the PCB, wherein the socket comprises a plurality of pogo pin connectors and wherein a pogo pin connector is operable to couple a ball on the BGA packaged DUT to a trace on the PCB, wherein the pogo pin connector of the socket comprises a first end in contact with the ball on the BGA packaged DUT and a second end in contact with the PCB, wherein the first end is thicker than a shaft of the pogo pin connector, and wherein the PCB comprises at least a ground plane and a signal plane comprising signal traces, and wherein the ground plane is nearer to the second end relative to the signal plane.

The following detailed description together with the accompanying drawings will provide a better understanding of the nature and advantages of the present invention.

### BRIEF DESCRIPTION OF THE DRAWINGS

Embodiments of the present invention are illustrated by way of example, and not by way of limitation, in the figures of the accompanying drawings and in which like reference numerals refer to similar elements.

FIG. 1 illustrates an exemplary 0.5 mm BGA packaged integrated circuit (IC).

FIG. 2 illustrates an exemplary convention tester system for testing BGA packaged devices under test (DUTs) in accordance with an embodiment of the present invention.

FIG. 3 illustrates the cylindrical pogo pin contactor configuration in a conventional test socket used to test high frequency BGA devices.

FIGS. 4A and 4B illustrate graphs demonstrating the behavior of a conventional socket as frequency rises.

FIG. 5 illustrates the manner in which a pogo pin contactor can be optimized in accordance with an embodiment of the present invention.

FIG. 6 illustrates simulation results for the BGA ball interface of a conventional pogo pin contactor.

FIG. 7 illustrates simulation results for the coaxial transmission line part of a conventional pogo pin contactor.

FIG. 8 illustrates simulation results for the PCB interface part of a conventional pogo pin contactor.

FIGS. 9A and 9B illustrate the manner in which the BGA ball interface of a pogo pin contactor can be optimized for a 50-ohm impedance (single ended) in accordance with an embodiment of the present invention.

FIGS. 10A and 10B illustrate the manner in which the PCB interface of the pogo pin contactors can be optimized for a 50-ohm impedance (single-ended) in accordance with an embodiment of the present invention.

FIGS. 11A and 11B illustrate the manner in which the configuration illustrates in FIGS. 10A and 10B reduce parasitic noise in accordance with an embodiment of the present invention.

FIG. 12 illustrates the manner in which pulling the ground plane closer to signal vias at right angle transitions improves performance in accordance with embodiments of the present invention.

FIG. 13 illustrates the manner in which offsetting ground and signal discontinuities improves performance in accordance with an embodiment of the present invention.

FIG. 14 illustrates test results for the optimized pogo pin contactor designed in accordance with an embodiment of the present invention.

FIG. 15 depicts a flowchart of an exemplary process of assembling a test system using pogo pin contactors in accordance with one embodiment of the present invention.

In the figures, elements having the same designation have the same or similar function.

### DETAILED DESCRIPTION OF THE INVENTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure as defined by the appended claims. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

For expository purposes, the term “horizontal” as used herein refers to a plane parallel to the plane or surface of an object, regardless of its orientation. The term “vertical” refers to a direction perpendicular to the horizontal as just defined. Terms such as “above,” “below,” “bottom,” “top,” “side,” “higher,” “lower,” “upper,” “over,” and “under” are referred to with respect to the horizontal plane.

Automotive applications are requiring increased use of RF/microwave frequency bands, from low RF signals through millimeter-wave frequencies at 77 GHz in radar applications. As these high-frequency signals become more integral parts of the worldwide driving experience, effective test solutions become more critical for designers developing new automotive RF/microwave circuits, as well as production facilities seeking efficient methods for verifying the performance of these radar circuits. While lower-frequency testers are in abundance, and automotive applications employ a wide range of wireless frequencies, a growing concern in automotive markets is for the accurate and cost-effective testing of 77-GHz automotive radar systems for instance. This interest stems from the fact that historically, test and measurement equipment operating at such high frequencies has neither been commonplace nor cost-effective.

A number of different automotive radar-based safety applications make use of frequencies from 76 to 77 GHz, for adaptive cruise control (ACC), blind-spot detection (BSD), emergency braking, forward collision warning (FCW), and rear collision protection (RCP). For example, in a collision warning system, an automotive radar sensor can detect and track objects within the range of the transmitted and returned radar signals, automatically adjusting a vehicle's speed and distance in accordance with the detected targets. Embodiments of the present invention advantageously provide cost-effective and efficient solutions for testing integrated circuits (ICs) to be used in automotive radar systems.

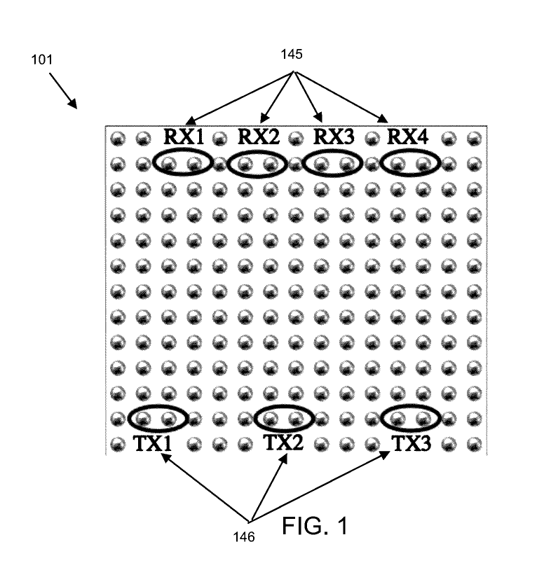

FIG. 1 illustrates an exemplary 0.5 mm BGA packaged integrated circuit (IC). The IC 101 comprises 3 differential millimeter wave (mmW) transmit ports and 4 differential mmW receive ports. The IC illustrated in FIG. 1 may, for instance, be intended for a module that is incorporated into a collision avoidance radar for a self-driving automobile, as discussed above. In order to test the 7 mmW ports on this IC, an 80 GHz contactor solution is required. Further, because the ICs are manufactured in a high volume environment, it is important that the solution also have a 150-micron compliance. Embodiments of the present invention advantageously provide a pogo pin contactor solution that has both 80 GHz millimeter wave test capability along with 150-micron compliance for rugged, reliable performance in a high volume manufacturing environment. Further, embodiments of the present invention provide a pogo pin contactor design that operates at millimeter wave frequencies and maintains a 50 ohm profile along its body.

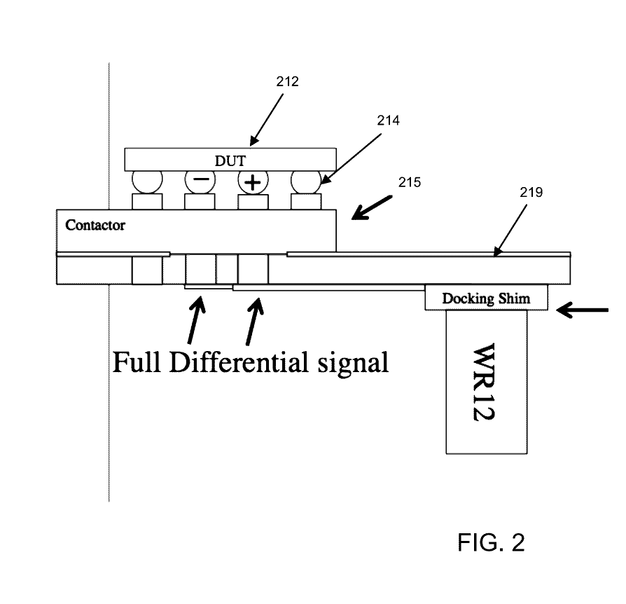

FIG. 2 illustrates an exemplary conventional tester system for testing BGA packaged devices under test (DUTs) in accordance with an embodiment of the present invention. The test head of an automated test equipment (ATE) apparatus communicates with DUT 212 (comprising a ball grid array 214) through a printed circuit board (PCB) 219 and waveguide WR12. Typically, a socket is used in order to make contact between DUT 212 and PCB 219. The socket should typically allow reliable electrical contact and be durable enough to handle several hundred insertions over the lifetime of the socket. The socket comprises a contactor 215 that is operable to make contact between the balls 214 of the BGA and the traces on PCB 219. Conventional sockets employ multiple contactor options including a conducting elastomer used with a flexible PCB, or a conducting elastomer used with a metal top hat, or a pogo pin. However, as discussed above, conducting elastomer has several deficiencies, which make it undesirable for high volume manufacturing environments.

Accordingly, embodiments of the present invention provide a socket that uses pogo pin contactors, wherein the pogo pin is suspended in a cylindrical hole in a metal block within the socket to create a coaxial transmission line. Further, by optimizing the profile of the pogo pin for 50 ohms along its body, embodiments of the present invention provide a pogo pin contactor design, which can operate 80 GHz millimeter wave frequencies while maintaining 150-micron compliance. Moreover, the metal block of the socket that the pogo pin contactors are passed through provides superior isolation and minimizes cross-talk between the signals.

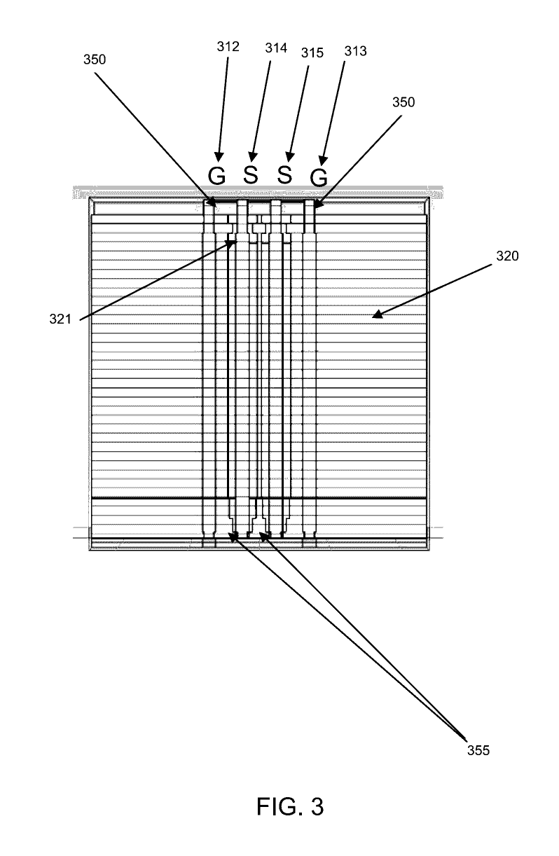

FIG. 3 illustrates the cylindrical pogo pin contactor configuration in a conventional test socket used to test high frequency BGA devices. The socket comprises four cylindrical spring-loaded pogo pins, wherein two of the pins, 312 and 313, are Ground pins, and the other two pins, 314 and 315, are Signal pins. The pins comprise an inline “GSSG” configuration (Ground Signal Signal Ground), wherein the Signal pins communicate a differential data signal with a Ground signal on each side. As shown in FIG. 3, the two Signal pins are suspended in a cylindrical hole in the metal block 320, wherein the Signal pins are held in place in a proper concentric position relative to the cylindrical cavity using insulating plastic pieces 321. By comparison, the Ground pins can be flush against the metal block because the metal block is also at ground potential. In other words, the Ground pins can fill up the cylindrical cavity in the metal block because there is no active signal that needs to be passed through them.

Both ends of the pogo pins are typically spring-loaded. Because the pins are used to propagate millimeter waves, the diameter of the Signal pins is significantly smaller than 1 mm. The tips of the pogo pins 350 protrude into air above the metal block so that contact can be made with the BGA packaged DUT. The bottom of the pogo pins 355 make contact with the traces on a PCB.

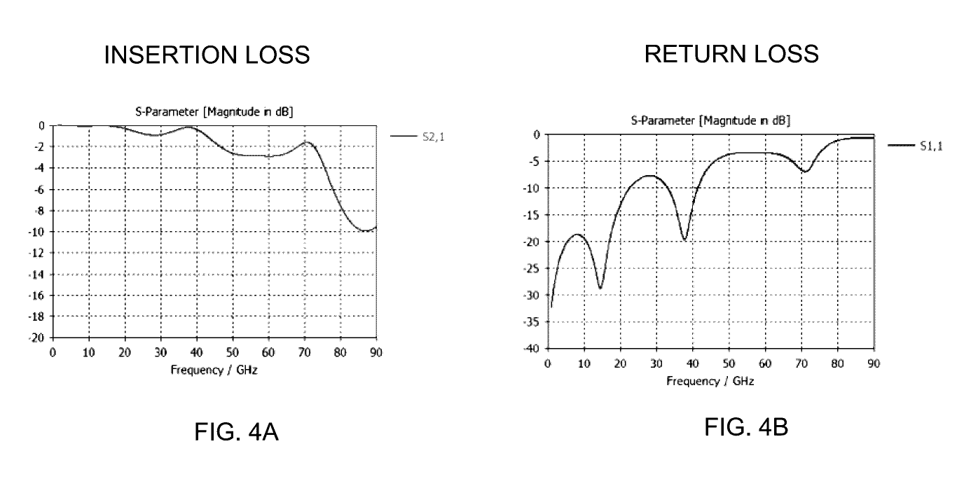

Conventional test sockets have satisfactory compliance but are limited to less than 40 GHz performance. FIGS. 4A and 4B illustrate graphs demonstrating the behavior of a conventional socket as frequency rises. As shown in FIGS. 4A and 4B, as frequency increases over 40 GHz, both the insertion loss and return loss deteriorate. For example, the insertion loss at 80 GHz is approximately −8 dB while the return loss is approximately 0 to −5 dB, which is unworkable for most applications.

One reason the pogo pin contactor design in a conventional socket is not able to support higher frequencies is because while the coaxial shaft of the pogo pin contactor may be optimized for a single-ended 50 ohm impedance, the ends of the pogo pins are not similarly optimized for a single-ended 50 ohm impedance at 80 GHz (or a 100-ohm differential impedance). Because the pogo pin ends are not similarly optimized, the short wavelength characteristic of millimeter waves causes reflections and other irregularities as a result of the discontinuities between the pogo pin coaxial shaft and the ends. Consequently, high frequencies over 80 GHz cannot be supported.

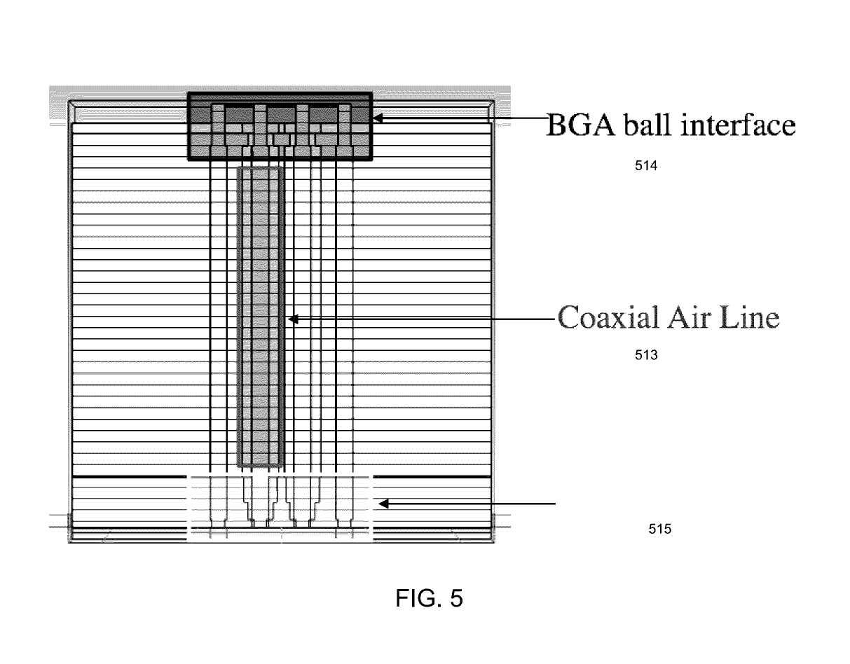

FIG. 5 illustrates the manner in which a pogo pin contactor can be optimized in accordance with an embodiment of the present invention. As will be further explained below, embodiments of the present invention optimize the pogo pin ends, the BGA ball interface 514 and the PCB interface 515, for a single-ended 50 ohm impedance in addition to the coaxial shaft 513. In other words, embodiments of the present invention consider the pogo pin contactor in three distinct regions and optimize each region to conform it to a 50-ohm impedance. By comparison, conventional pogo pin contactors simply configure the dimensions of the coaxial shaft for a 50-ohm impedance while ignoring the ends of the pogo pins.

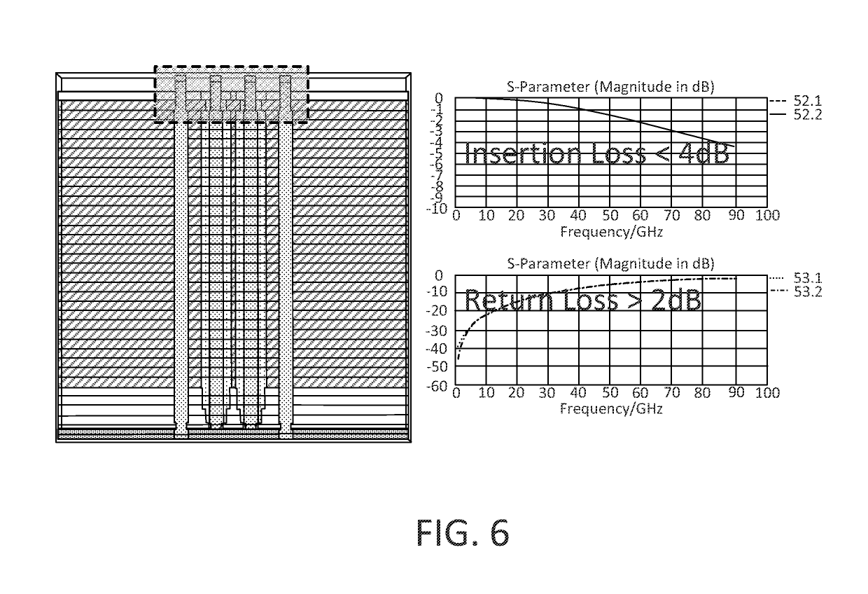

Simulation results also show that the ends of the pogo pin contactors in conventional sockets are not optimized to minimize reflections and other irregularities. FIG. 6 illustrates simulation results for the BGA ball interface of a conventional pogo pin contactor. The top ends of the pogo pin contactors protrude beyond the plastic plates 321 and make contact with the balls of the BGA packaged DUT. As shown in FIG. 6, above 80 GHz, the insertion loss deteriorates to over 4 dB, which is a significant loss compared to the relatively nominal loss of approximately 1 to 2 dB loss at 40 GHz shown in FIG. 4A. Also, the return loss for the BGA ball interface is only 2 dB below zero, which means that instead of transmitting through, most of the signal at frequencies over 80 GHz gets reflected back. Accordingly, there is a need to re-configure the design of the BGA ball interface of the pogo pin contactor.

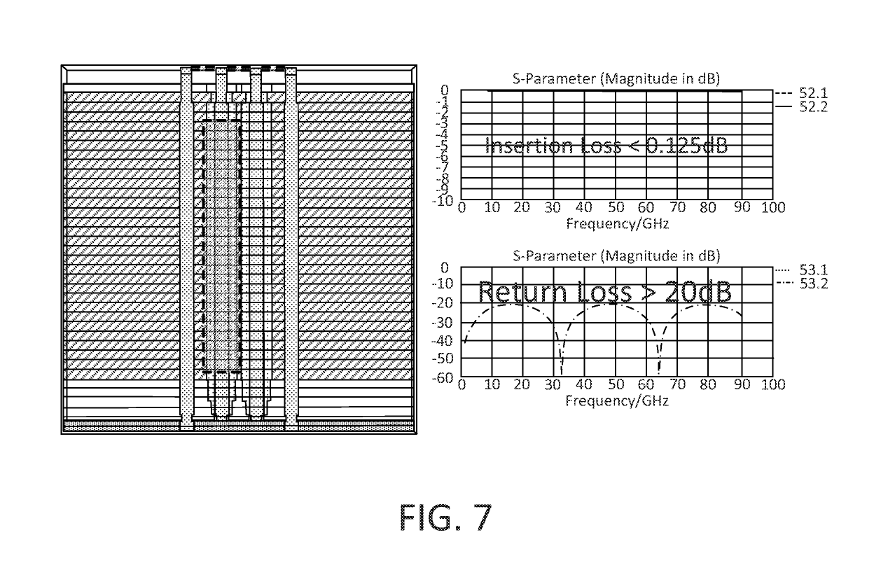

FIG. 7 illustrates simulation results for the coaxial transmission line portion of a conventional pogo pin contactor. As shown in FIG. 7, above 80 GHz, the insertion loss for the coaxial shaft is below 0.125 dB while the return loss is over 20 dB below zero. Both the losses are within an acceptable range, which indicates that the coaxial shaft part of the pogo pin contactor is substantially configured for a single-ended 50-ohm impedance.

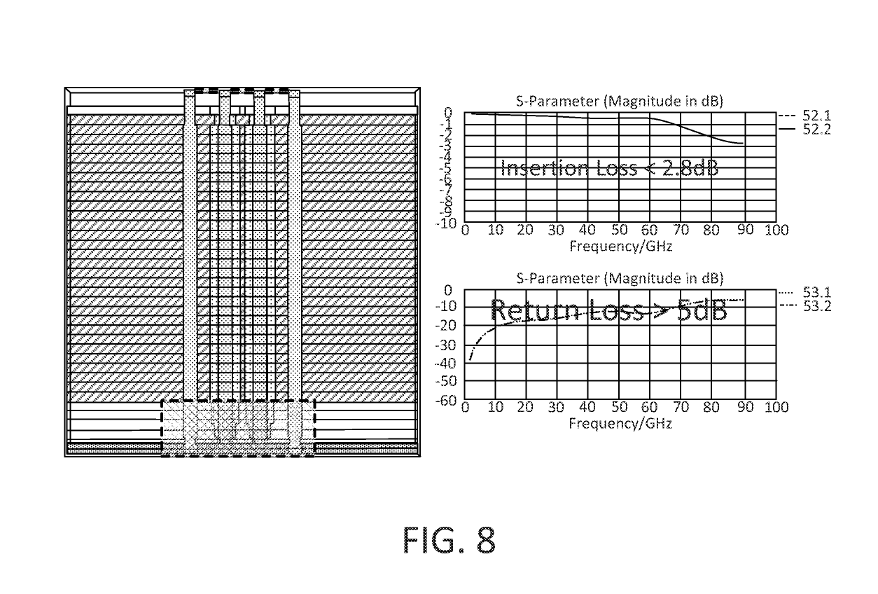

FIG. 8 illustrates simulation results for the PCB interface portion of a conventional pogo pin contactor. The bottom ends of the pogo pin contactor touch down and make contact with the copper traces of a planar PCB board. As shown in FIG. 8, above 80 GHz, the insertion loss deteriorates to over 2.8 dB, while the return loss is approximately 5 dB below zero. The ranges of the two losses indicate that the PCB interface is not nearly as lossy as the BGA ball interface, however, it is not as efficient as the coaxial shaft either and needs to be re-configured.

Accordingly, embodiments of the present invention address optimizing both the BGA ball interface and the PCB interface of a pogo pin contactor for a single-ended 50 ohm impedance (or a differential 100-ohm impedance). With the wavelengths for millimeter waves, every piece of the pogo pin structure needs to be optimized for 50 ohm impedance, otherwise, it results in undesirable reflections within the structure. Embodiments of the present invention optimize the entire structure of the pogo pin for a 50-ohm impedance including the tips.

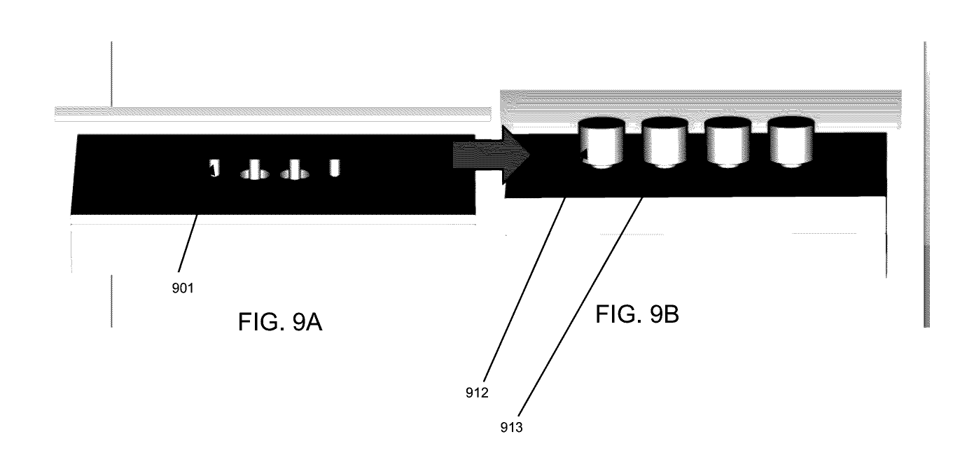

FIGS. 9A and 9B illustrate the manner in which the BGA ball interface of a pogo pin contactor can be optimized for a 50-ohm impedance (single ended) in accordance with an embodiment of the present invention. Pogo pin tips are typically designed to be narrower than the coaxial shaft of the pogo pin contactor to allow the pins to be easily secured by the insulating plastic plates 321. For example, in certain prior embodiments such as the one shown in FIG. 921, the pogo pin tips 921 are narrower than the coaxial body of the tip. Embodiments of the present invention, however, significantly increase the size of the pogo diameter in air relative to the original pogo diameter to obtain a 100 ohm differential impedance for the pogo ends. For example, as shown in FIG. 9B, the pogo diameter of pin 912 in air is significantly larger than the diameter of the pogo contactor end shown in FIG. 9A.

In one embodiment of the present invention, the pogo pin end 912 making contact with the BGA interface is also larger than the coaxial shaft of the pogo tip. In other words, the optimized pogo pin has thick ends 912 (relative to the shaft 913), shaped like dumb bells as shown in FIG. 9B. By increasing the size of the pogo pin tip, the BGA ball interface of the pogo pin contactor can be configured for a 50 ohm single-ended impedance. In one embodiment, the diameter of the pogo pin ends will be determined by the medium in which the ends interface with the BGA. For example, in a regular tester system, such as the one shown in FIG. 2, the ends protrude out from the metal block into air where they interface with the BGA. Accordingly, the air medium determines how thick the pogo pin ends can be configured. In one embodiment, the GSSG pogo diameter optimized for 100-ohm differential signal in free space is 0.32 mm for a 0.5 mm pitch, where the pitch is the center to center distance between the pogo pins.

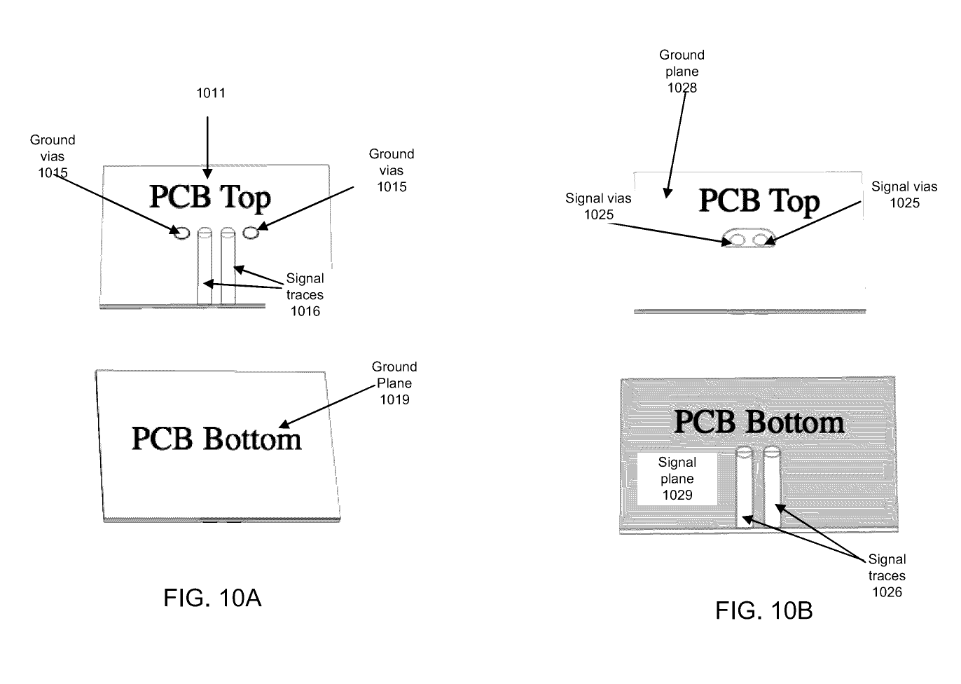

FIGS. 10A and 10B illustrate the manner in which the PCB interface of the pogo pin contactors can be optimized for a 50-ohm impedance (single-ended) in accordance with an embodiment of the present invention. A PCB typically comprises multiple layers, for example, one layer may be a ground plane, whereas another layer may comprise all the traces that communicate signals. In typical PCB configurations, such as the one shown in FIG. 10A, the ground plane is typically below the top plane comprising the traces for communicating signals. As shown in FIG. 10A, when the signal reaches the PCB Top plane 1011, it begins to travel via signal traces 1016 before the ground signal reaches ground plane 1019 via ground vias 1015. In typical applications with longer wavelengths this is not a problem, however, with short millimeter wavelengths, the discrepancy in the timing between the signal and ground can result in parasitic noise.

Embodiments of the present invention address this discrepancy by configuring the ground plane 1028 to be above the plane with the signal traces 1029. The signal is communicated via the coaxial body of the pogo pin contactor through signal vias 1025 and starts traveling across the PCB when it reaches the signal traces 1026. The ground signals, meanwhile, reach the ground plane 1028 before the signal reaches the signal plane 1029.

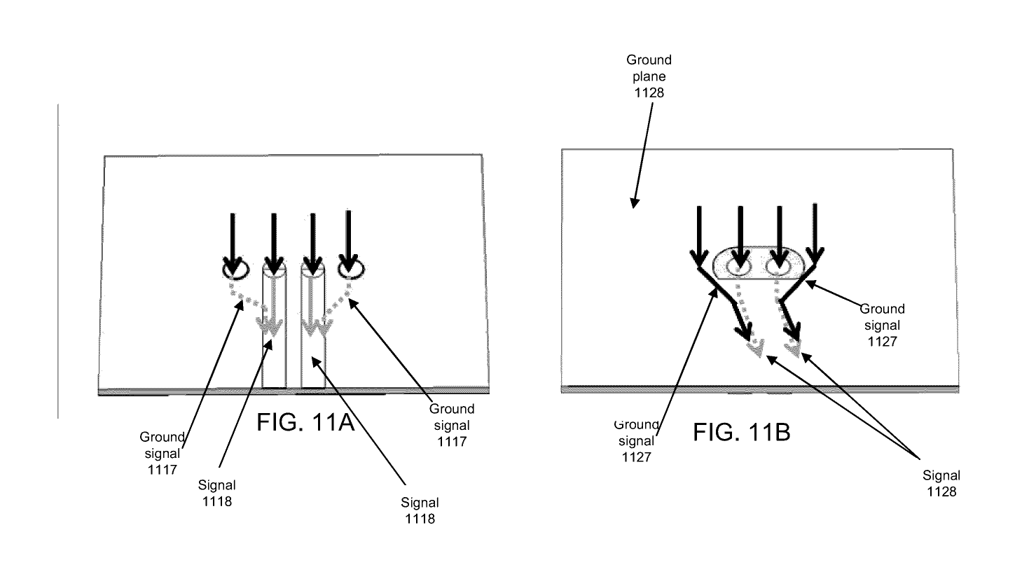

FIGS. 11A and 11B illustrate the manner in which the configuration illustrates in FIGS. 10A and 10B reduce parasitic noise in accordance with an embodiment of the present invention. FIG. 11A illustrates the manner in which the ground and signal behave on the PCB Top plane 1011 of FIG. 10A. Because the signal 1118 is already traveling across the traces on the PCB before the ground signal 1117 hits the ground plane 1019, the ground signal 1117 has a further distance to travel to merge with signal 1118. This ground lag results a lossy transition at higher frequency (because of the corresponding smaller wavelengths of millimeter waves).

By comparison, moving the ground plane to the top, as shown in FIG. 11B, results in the ground signal 1127 reaching the PCB Top ground plane 1128 prior to the signals 1128 passing through the vias and reaching the traces. Accordingly, as shown in FIG. 11B, the ground signals 1127 have a shorter distance to travel to merge with signals 1128 and ground lag is reduced. In other words, by introducing a slight delay in the path of signal 1128, the ground lag can be reduced. Comparing FIGS. 11A and 11B, it is apparent that the ground signals do not need to travel as long in a diagonal path to merge with the signals in FIG. 11B relative to FIG. 11A. Reducing ground lag and smoothening the transition for the signals, removes parasitic noise.

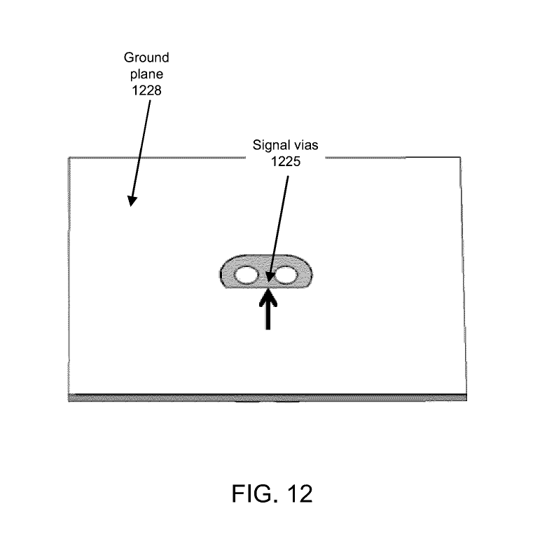

FIG. 12 illustrates the manner in which pulling the ground plane closer to signal vias at right angle transitions improves performance in accordance with embodiments of the present invention. Pulling the ground plane 1228 closer to signal vias 1225 minimizes the dielectric gap and is another technique employed by embodiments of the present invention to reduce parasitic noise.

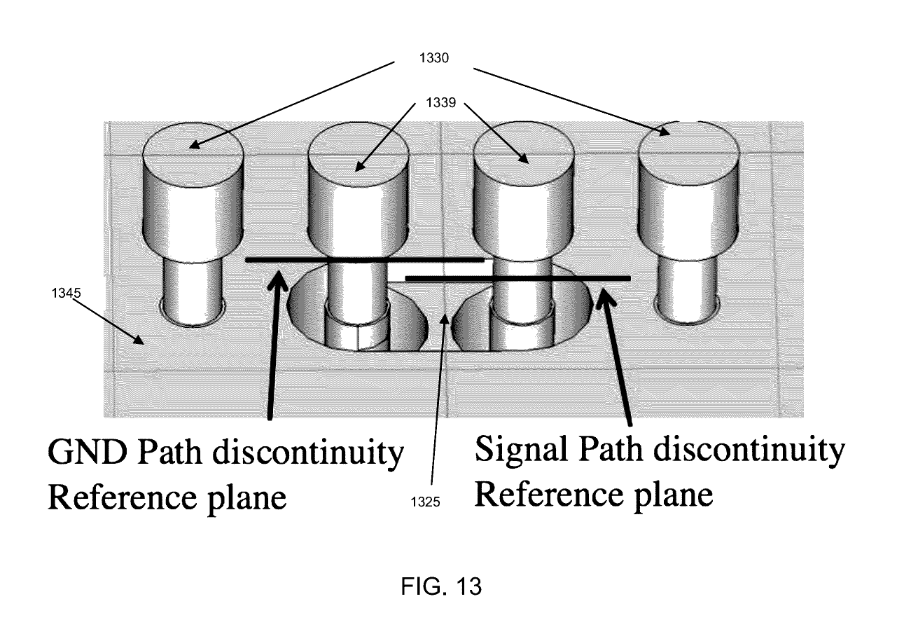

FIG. 13 illustrates the manner in which offsetting ground and signal discontinuities improves performance in accordance with an embodiment of the present invention. Offsetting discontinuities or minimizing discontinuities at one reference point typically improves performance of electrical transmission. If both ground signals 1330 and signals 1339 reach plane 1345 at the same time, the number of discontinuities at reference plane 1345 is higher as compared to the embodiment of FIG. 13. In the embodiment illustrated in FIG. 13, region 1325 of plane 1345 is milled down (or sawed down) so as to stagger the discontinuity reference planes for the ground path and the signal path. Accordingly, the signals 1339 have an earlier discontinuity reference plane than the ground signals 1330. This technique also reduces parasitic noise and, further, by graduating the discontinuities, performance is typically improved.

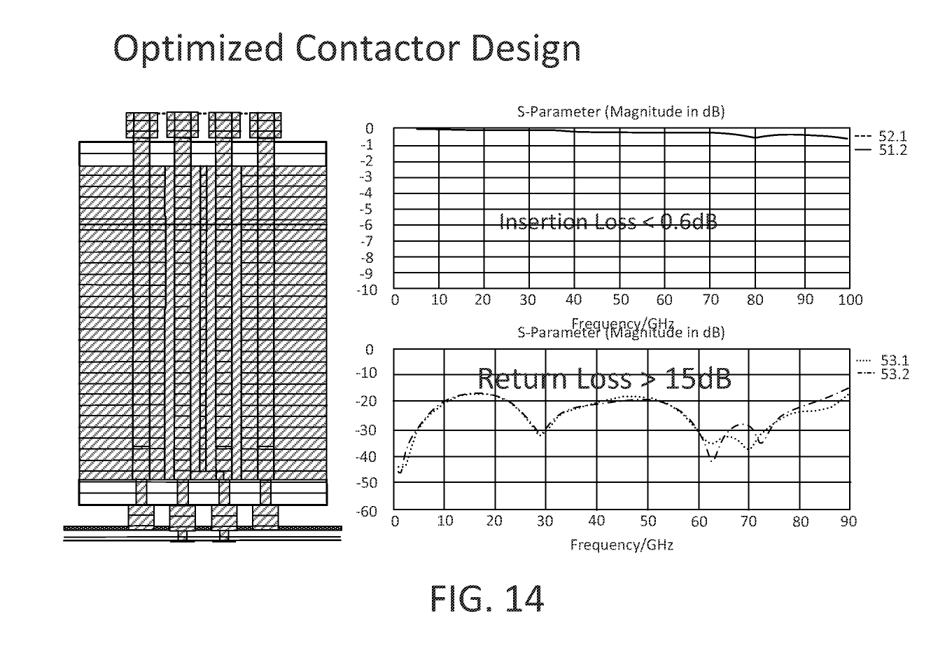

FIG. 14 illustrates test results for the optimized pogo pin contactor designed in accordance with an embodiment of the present invention. As seen in FIG. 14, the insertion loss of the optimized pogo pin design is less than 0.6 dB while the return loss is over 15 dB below 0 at 80 GHz frequencies. Accordingly, pogo pins designed in accordance with principles of the present invention yield far better results than the results of conventional sockets shown in FIGS. 4A and 4B.

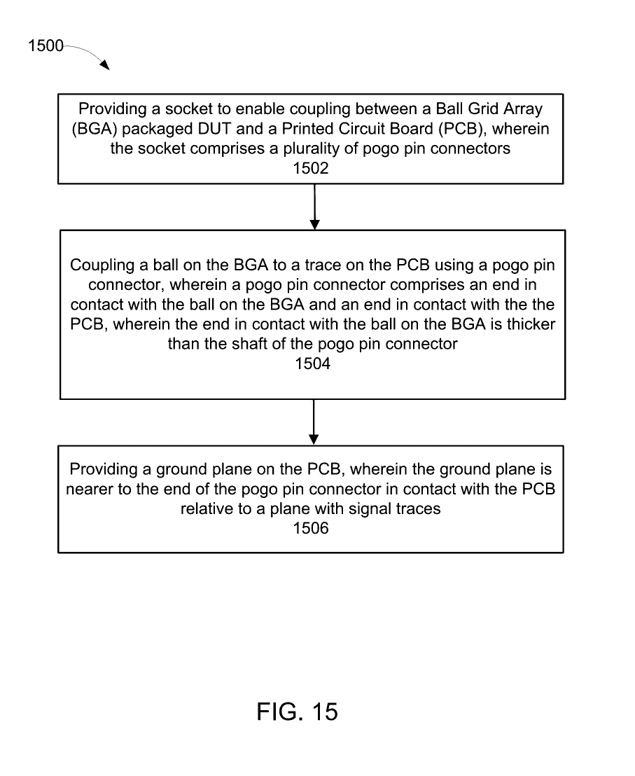

FIG. 15 depicts a flowchart of an exemplary process of assembling a test system using pogo pin contactors in accordance with one embodiment of the present invention. The invention, however, is not limited to the description provided by flowchart 1500. Rather, it will be apparent to persons skilled in the relevant art(s) from the teachings provided herein that other functional flows are within the scope and spirit of the present invention. Flowchart 1500 will be described with continued reference to exemplary embodiments described above, though the method is not limited to those embodiments.

At step 1502, a socket is provided to enable coupling between a Ball Grid Array (BGA) packaged DUT and a Printed Circuit Board (PCB), wherein the socket comprises a plurality of pogo pin connectors and wherein the PCB comprises a plurality of layers.

At step 1504, a ball on the BGA is coupled to a trace on the PCB using a pogo pin connector, wherein the pogo pin connector comprises an end in contact with the ball on the BGA and an end in contact with the PCB, wherein the end in contact with the ball on the BGA is thicker than the shaft of the pogo pin connector.

At step 1506, a ground plane is provided on the PCB, wherein the ground plane is nearer to the end of the pogo pin connector in contact with the PCB relative to a plane on the PCB with signal traces.

While the foregoing disclosure sets forth various embodiments using specific block diagrams, flowcharts, and examples, each block diagram component, flowchart step, operation, and/or component described and/or illustrated herein may be implemented, individually and/or collectively, using a wide range of hardware configurations. In addition, any disclosure of components contained within other components should be considered as examples because many other architectures can be implemented to achieve the same functionality.

The process parameters and sequence of steps described and/or illustrated herein are given by way of example only. For example, while the steps illustrated and/or described herein may be shown or discussed in a particular order, these steps do not necessarily need to be performed in the order illustrated or discussed. The various example methods described and/or illustrated herein may also omit one or more of the steps described or illustrated herein or include additional steps in addition to those disclosed.

It should also be understood, of course, that the foregoing relates to exemplary embodiments of the invention and that modifications may be made without departing from the spirit and scope of the invention as set forth in the following claims.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as may be suited to the particular use contemplated.

Embodiments according to the invention are thus described. While the present disclosure has been described in particular embodiments, it should be appreciated that the invention should not be construed as limited by such embodiments, but rather construed according to the below claims.

What is claimed is:

1. A method of assembling a test system using pogo pin contactors, the method comprising:
positioning a socket to enable coupling between a Ball Grid Array (BGA) packaged DUT and a Printed Circuit Board (PCB), wherein the socket comprises a plurality of pogo pin connectors;
coupling a ball on the BGA packaged DUT to a trace on the PCB using a pogo pin connector of the socket, wherein the pogo pin connector comprises a first end in contact with the ball on the BGA packaged DUT and a second end for contact with the PCB, wherein the first end is thicker than a shaft of the pogo pin connector; and
contacting the second end of the pogo pin connector to the PCB, wherein a ground plane on the PCB is nearer to the second end relative to a plane with signal traces.

2. The method of claim 1, wherein the coupling further comprises:
configuring a diameter of the first end of the pogo pin connector to substantially match a single ended 50 ohm impedance.

3. The method of claim 2, wherein the diameter is substantially 0.32 mm for a 0.5 mm pitch in free space.

4. The method of claim 1, further comprising:
configuring a subset of the plurality of pogo pin connectors into a differential configuration, wherein the subset comprises four pogo pin connectors arranged in a Ground, Signal, Signal, Ground (GSSG) configuration, wherein two of the pogo pin connectors are configured to transmit a Ground signal and two of the pogo pin connectors are configured to transmit a data Signal.

5. The method of claim 4, further comprising:
configuring the two Signal pogo pin connectors to pass through vias on the ground plane on the PCB, wherein the Ground signal reaches the ground plane before the Signal passes through the vias and reaches the signal traces, and wherein the configuring is operable to reduce ground lag.

6. The method of claim 5, further comprising:
pulling the ground plane closer to the vias at right angle transitions, wherein the pulling is operable to improve performance and reduce parasitic noise.

7. An apparatus for testing DUTs comprising:
a socket operable to enable coupling between a Ball Grid Array (BGA) packaged DUT and a Printed Circuit Board (PCB), wherein the socket comprises a plurality of pogo pin connectors, and
wherein a pogo pin connector of the socket is operable to couple a ball on the BGA packaged DUT to a trace on the PCB, wherein the pogo pin connector comprises a first end operable for contact with the ball on the BGA packaged DUT and a second end operable for contact with the PCB, wherein the first end is thicker than a shaft of the pogo pin connector, and
wherein the PCB comprises at least a ground plane and a signal plane comprising signal traces, and wherein the ground plane is nearer to the second end relative to the signal plane.

8. The apparatus of claim 7, wherein a diameter of the first end of the pogo pin connector is configured to substantially match a single ended 50 ohm impedance.

9. The apparatus of claim 8, wherein the diameter is 0.32 mm for a 0.5 mm pitch in free space.

10. The apparatus of claim 7, wherein a subset of the plurality of pogo pin connectors is configured into a differential configuration, wherein the subset comprises four pogo pin connectors arranged in a Ground, Signal, Signal, Ground (GSSG) configuration, wherein two of the pogo pin connectors are configured to transmit a Ground signal and two of the pogo pin connectors are configured to transmit a differential data Signal.

11. The apparatus of claim 10, wherein the PCB further comprises:
vias on the ground plane on the PCB configured to pass the two Signal pogo pin connectors to the signal traces on the signal plane, wherein the Ground signal reaches the ground plane before the data Signal reaches the signal plane.

12. The apparatus of claim 11, wherein the ground plane is pulled closer to the vias at right angle transitions in order to improve performance and reduce parasitic noise.

13. The apparatus of claim 12, wherein the ground plane is milled down in order to stagger discontinuity reference planes for a path of the Ground signal and a path of the Signal.

14. An automated testing equipment (ATE) apparatus comprising:
a waveguide operable to communicate signals from a test head of the ATE to a Printed Circuit Board (PCB), wherein the PCB comprises signal traces operable to conduct signals; and
a socket to enable coupling between a Ball Grid Array (BGA) packaged DUT and the PCB, wherein the socket comprises a plurality of pogo pin connectors, and
wherein a pogo pin connector is operable to couple a ball on the BGA packaged DUT to a trace on the PCB, wherein the pogo pin connector of the socket comprises a first end in contact with the ball on the BGA packaged DUT and a second end in contact with the PCB, wherein the first end is thicker than a shaft of the pogo pin connector, and
wherein the PCB comprises at least a ground plane and a signal plane comprising signal traces, and wherein the ground plane is nearer to the second end relative to the signal plane.

15. The ATE of claim 14, wherein a diameter of the first end of the pogo pin connector is configured to substantially match a single ended 50 ohm impedance.

16. The ATE of claim 15, wherein the diameter is 0.32 mm for a 0.5 mm pitch in free space.

17. The apparatus of claim 7, wherein a subset of the plurality of pogo pin connectors is configured into a differential configuration, wherein the subset comprises four pogo pin connectors arranged in a Ground, Signal, Signal, Ground (GSSG) configuration, wherein two of the pogo pin connectors are configured to transmit a Ground signal and two of the pogo pin connectors are configured to transmit a data Signal.

18. The ATE of claim 14, wherein the PCB further comprises:
vias on the ground plane on the PCB configured to pass the two Signal pogo pin connectors to the signal traces on the signal plane, wherein the Ground signal reaches the ground plane before the Signal reaches the signal plane.

19. The ATE of claim 18, wherein the ground plane is pulled closer to the vias at right angle transitions in order to improve performance and reduce parasitic noise.

20. The ATE of claim 19, wherein the ground plane is milled down in order to stagger discontinuity reference planes for a path of the Ground signal and a path of the Signal.

21. The ATE of claim 14, wherein the ball on the BGA packaged DUT is electrically coupled to a port on the DUT and is able to test a functionality of the port in the frequency range of 75 to 85 GHz.
